(19) United States
(12) Patent Application Publication
(10) Pub. No.: US 2020/0283884 A1
(43) Pub. Date: Sep. 10, 2020

(54) MASK PLATE ASSEMBLY

(71) Applicant: Wuhan China Star Optoelectronics Semiconductor Display Technology Co., Ltd., Wuhan (CN)

(72) Inventor: Zhiming LIN, Wuhan (CN)

(21) Appl. No.: 16/490,908

(22) PCT Filed: Mar. 7, 2019
(86) PCT No.: PCT/CN2019/077298

§ 371 Date: Sep. 4, 2019

(51) Int. Cl. C23C 14/04; C23C 14/24; C23C 14/00

(52) U.S. Cl. CPC C23C 14/042; C23C 14/0021; C23C 14/24

(57) ABSTRACT

A mask plate assembly for evaporation is provided, which includes matching mask plates forming a complete set. Each mask plate includes a main body and an opening region, and the opening region is provided with a block portion, at least one connector, and an evaporation zone. The connector is connected to the main body and the block portion. A size of the connector of one of the at least two mask plates is the same as a size of the evaporation zone of the other mask plate and the positions of the connector and the evaporation zone thereof are overlapped. The evaporation zones in the at least two mask plates are matched each other.

### FIELD OF INVENTION

The present invention relates to a field of display technology, and more particularly, to a mask plate assembly for evaporation.

### BACKGROUND OF INVENTION

At present, the mask plate is mainly used as a mask mold in the evaporation process of the organic light-emitting diode (OLED) device production technology. The material is evaporated to a predetermined position through the mask mold, whereby the evaporation of the red, blue and green pixels is completed.

With the rapid development of electronic technology, the screen of the display is getting bigger. In order to provide a better visual experience to users, the full screen becomes the development trend of intelligent electronics. Not only the screen disposed in the front of the intelligent device but also the camera, earpiece and other components; the camera and the earpiece occupy a certain area, thereby limiting the screen size on the front of the device.

Currently, a groove is used to realize the placement of the camera in the front of the device. In order to meet the needs of the full screen, it is a development trend to integrate the camera into the screen on the front of the mobile phone. Therefore, a block area needs to be arranged in a region corresponding to the camera in the opening region of the mask plate, so that the material is prevented from being evaporated on the region. However, if the block area is set independently, it cannot be defined in the main body of the mask plate. On the contrary, if the block area is connected to the body, the connection portion in the opening region of the mask plate prevents the evaporation of the material to the display, which may cause the display to be abnormal. Therefore, the current single evaporation process and the mask plate cannot meet the requirement of the component, like a camera, to be built into the screen.

### SUMMARY OF INVENTION

The invention provides a mask plate assembly for evaporation to solve the technical problem that the existing mask plate adversely affects the realization of the full screen. Because the block area corresponding to the camera and/or other component in the opening region of the mask plate is set independently and cannot be connected to the main body of the mask plate, it is difficult to implement the evaporation process of the OLED which can meet the requirement to build the component, like a camera, into the screen.

In order to solve the above problems, the technical solution provided by the present invention is as follows.

The present invention provides a mask plate assembly for evaporation, which includes at least two mask plates forming a complete set. Each mask plate includes a main body and an opening region. The opening region is provided with a block portion, at least one connector, and an evaporation zone. The connector is connected to the main body and the block portion. A size of the connector of one of the at least two mask plates is the same as a size of the evaporation zone of the other mask plate, and the positions of the connector and the evaporation zone thereof are overlapped. The evaporation zone of at least two mask plates are matched each other. Each of the mask plates is one-piece structure. The block portion, the connector, and the evaporation zone in each of the at least two mask plates are formed by the same etching process.

In one embodiment of the prevent invention, the mask plate assembly includes a first mask plate and a second mask plate.

In one embodiment of the prevent invention, the first mask plate forms a first connector, a second connector, a third connector and a fourth connector in the opening region thereof.

In one embodiment of the prevent invention, each of the first connector, the second connector, the third connector, and the fourth connector has one end connected to the main body and another end connected to the block portion.

In one embodiment of the prevent invention, the first connector, the second connector, the third connector, the fourth connection, and the block portion together define a cross structure, and the block portion is located at an intersection of the cross structure.

In one embodiment of the prevent invention, the evaporation zone of the second mask plate is divided into four first sub-evaporation zones, and the contours of the four first sub-evaporation zones are substantially the same as the shapes of the first connector, the second connector, the third connector, and the fourth connector respectively.

The present invention further provides a mask plate assembly for evaporation, which includes at least two mask plates forming a complete set. Each mask plate includes a main body and an opening region, and the opening region is provided with a block portion, at least one connector, and an evaporation zone. The connector is connected to the main body and the block portion. A size of the connector of one of the at least two mask plates is the same as a size of the evaporation zone of the other mask plate and the positions of the connector and the evaporation zone thereof are overlapped. The evaporation zone in each of the at least two mask plates are matched each other.

In one embodiment of the prevent invention, the mask plate assembly includes a first mask plate and a second mask plate.

In one embodiment of the prevent invention, the first mask plate forms a first connector, a second connector, a third connector and a fourth connector in the opening region thereof.

In one embodiment of the prevent invention, each of the first connector, the second connector, the third connector, and the fourth connector has one end connected to the main body and another end connected to the block portion.

In one embodiment of the prevent invention, the first connector, the second connector, the third connector, and the fourth connector has a shape in strip.

In one embodiment of the prevent invention, the first connector and the second connector are connected as a straight line, and also the third connector and the fourth connector are connected as a straight line.

In one embodiment of the prevent invention, the first connector, the second connector, the third connector, the fourth connection, and the block portion together define a cross structure, and the block portion is located at an intersection of the cross structure.

In one embodiment of the prevent invention, the evaporation zone of the second mask plate is divided into four first sub-evaporation zones, and the contours of the four first sub-evaporation zones are substantially the same as the shapes of the first connector, the second connector, the third connector, and the fourth connector respectively.

In one embodiment of the prevent invention, the mask plate assembly further includes a third mask plate.

In one embodiment of the prevent invention, the evaporation zone of the second mask plate is divided into two second sub-evaporation zones, and the contours of the two second sub-evaporation zones are substantially the same as the shapes of the first connector and the second connector of the first mask plate respectively.

In one embodiment of the prevent invention, the evaporation zone of the third mask plate is divided into two third sub-evaporation zones, and the contours of the two third sub-evaporation zones are substantially the same as the shapes of the third connector and the fourth connector of the first mask plate respectively.

In one embodiment of the prevent invention, the mask plate assembly further includes a fourth mask plate and a fifth mask plate.

In one embodiment of the prevent invention, the contours of each evaporation zone of the second mask plate, the third mask plate, the fourth mask plate and the fifth mask plate are substantially the same as the shapes of the first connector, the second connector, the third connector and the fourth connector of the first mask plate respectively.

In one embodiment of the prevent invention, the shape of the block portion of the first mask plate is a circular or a rectangular.

According to the mask plate assembly provided by the invention, at least two mask plates forming a complete set are provided to complete the evaporation process step by step, the specific area of the screen is not evaporated and/or plated with the material. Then, the camera is built in the screen and free from affection of the evaporating material, so that the full screen can be realized.

### DESCRIPTION OF DRAWINGS

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a schematic drawing showing a first mask plate according to embodiments of the present invention;

FIG. 2 is a schematic drawing showing a second mask plate according to a first embodiment of the present invention;

FIG. 3 is a schematic drawing showing a second mask plate according to a second embodiment of the present invention;

FIG. 4 is a schematic drawing showing a third mask plate according to the second embodiment of the present invention;

FIG. 5 is a schematic drawing showing a second mask plate according to a third embodiment of the present invention;

FIG. 6 is a schematic drawing showing a third mask plate according to the third embodiment of the present invention;

FIG. 7 is a schematic drawing showing a fourth mask plate according to the third embodiment of the present invention; and

FIG. 8 is a schematic drawing showing a fifth mask plate according to the third embodiment of the present invention.

### DETAILED DESCRIPTION OF PREFERRED EMBODIMENTS

The following description of each embodiment, with reference to the accompanying drawings, is used to exemplify specific embodiments which may be carried out in the present invention. Directional terms mentioned in the present invention, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present invention. In the drawings, components having similar structures are denoted by the same numerals.

The invention provides a mask plate assembly for evaporation to solve the technical problem that the existing mask plate adversely affects the realization of the full screen. Because the block area corresponding to the camera and/or other component in the opening region of the mask plate is set independently and cannot be connected to the main body of the mask plate, it is difficult to implement the evaporation process of the OLED which can meet the requirement to build the component, like a camera, into the screen.

The present invention provides a mask plate assembly including at least two mask plates forming a complete set, the mask plate includes a main body and an opening region, and the opening region is provided with a block portion, at least one connector, and an evaporation zone.

The block portion is used to shield corresponding area from evaporation of the material. The block portion may be circular or square, which is not limited herein, and has a shape similar to that of a component such as a camera built into the screen.

The connector is connected to the main body and the block portion, and is used for fixing the block portion and ensuring the connection stability of the block portion.

In the mask plates for matching use, a size of the connector of one of the two mask plates is the same as a size of an evaporation zone of the other mask plate, and the positions of the connector and the evaporation zone thereof are overlapped. Since only the area corresponding to the block portion does not require an evaporation material during evaporation, the connector is added for the stability of the connection of the block portion, and the area corresponding to the connector is blocked and cannot be evaporated with the material consequently. Therefore, at least two mask plates are required for the evaporation to ensure that there is no evaporation material in the corresponding area of the block portion, and the corresponding region of the connector is finally evaporated with the material.

The mask plate in the mask plate assembly is a one-piece structure, and a block portion, a connector, and an evaporation zone in each of the at least two mask plates are formed by the same etching process. The mask plate is integrally welded to the frame by stretching.

The present invention will be described in detail below with reference to some embodiments.

### First Embodiment

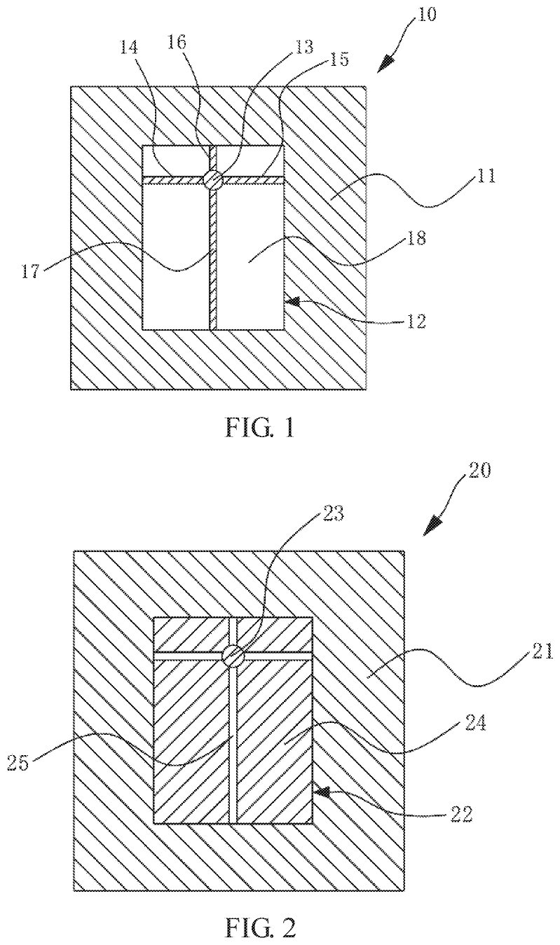

FIG. 1 and FIG. 2 are schematic diagrams of the mask plate used in conjunction with the present invention. The embodiment provides a mask plate assembly, including two matching mask plates, which are respectively a first mask plate 10 and a second mask plate 20.

The first mask plate 10 includes a main body 11 and an opening region 12 as shown in FIG. 1, and the opening region 12 is provided with a block portion 13, a first connector 14, a second connector 15, a third connector 16, a fourth connector 17, and an evaporation zone 18.

The first connector 14, the second connector 15, the third connector 16, and the fourth connector 17 each are connected to the block portion 13 at one end thereof, and the opposite end thereof is connected to the main body 11. The block portion 13 is connected to the main body 11 by the four connectors.

The first connector 14, the second connector 15, the third connector 16 and the fourth connector 17 are strip-shaped structures. The connection between the first connector 14 and the second connector 15 and the connection between the third connector 16 and the fourth connector 17 are straight lines. Straight line structure is easier to etch than the curve or bend structures.

The first connector, the second connector, the third connector, the fourth connector, and the block portion together define a cross structure, and the block portion is located at an intersection of the cross structure.

The block portion 13 has a circular structure and is located at a corresponding area in the opening region 12, and specifically is disposed corresponding to the camera area set in the display panel to shield the material from being evaporated thereon during evaporation.

The cross structure separates the evaporation zone 18 in the opening region 12 into four sub-evaporation zones. When the evaporation process is performed with the first mask plate 10, the evaporation zone 18 is evaporated with material, and the area corresponding to the block portion 13 and the four connectors is not evaporated with material.

As shown in FIG. 2, the second mask plate 20 includes a main body 21 and an opening region 22, and the opening region 22 is provided with a block portion 23, four connectors 24, and an evaporation zone 25.

The evaporation zone 25 of the second mask plate 20 is the same size as and overlaps with the connector of the first mask plate. Similarly, the connector 24 of the second mask plate 20 is the same size as and overlaps with the evaporation zone 18 of the first mask plate 10.

The evaporation zone 25 of the second mask plate 20 is separated into four first sub-evaporation zones by the block portion 23 and the four connectors 24. The four first sub-evaporation zones are the same size as and overlap with the first connector 14, the second connector 15, the third connector 16, and the fourth connector 17 of the first mask plate 10, respectively.

The mask plate assembly provided in this embodiment is used for evaporation twice during evaporation of the OLED material. First, the first evaporation is performed with the first mask plate 10, and the material is evaporated in the area of the OLED device corresponding to the evaporation zone 18 in the opening region 12. Then, the second evaporation is performed with the second mask plate 20, and the material is evaporated in the area of the OLED device corresponding to the evaporation zone 25 of the second mask plate 20. That is, the area blocked by the block portion 13 and the four connectors of the first mask plate 10, which is not evaporated with the evaporation material in the first evaporation is now supplemented with the evaporation material.

By employing the first mask plate 10 and the second mask plate 20 as a complete set, only the region corresponding to the block portion, i.e., the area reserved to set the component like camera in the screen, has no evaporation material thereon, is finally realized.

### Second Embodiment

As shown in FIGS. 1, 3 and 4, for the evaporation process to be more stable, the evaporation procedure of the OLED device can be divided into three periods. The mask plate assembly provided in this embodiment includes three matching mask plates, namely, a first mask plate 10, a second mask plate 30, and a third mask plate 40.

The first mask plate provided in this embodiment is the same as the first mask plate provided in the first embodiment, and details thereof are not described herein.

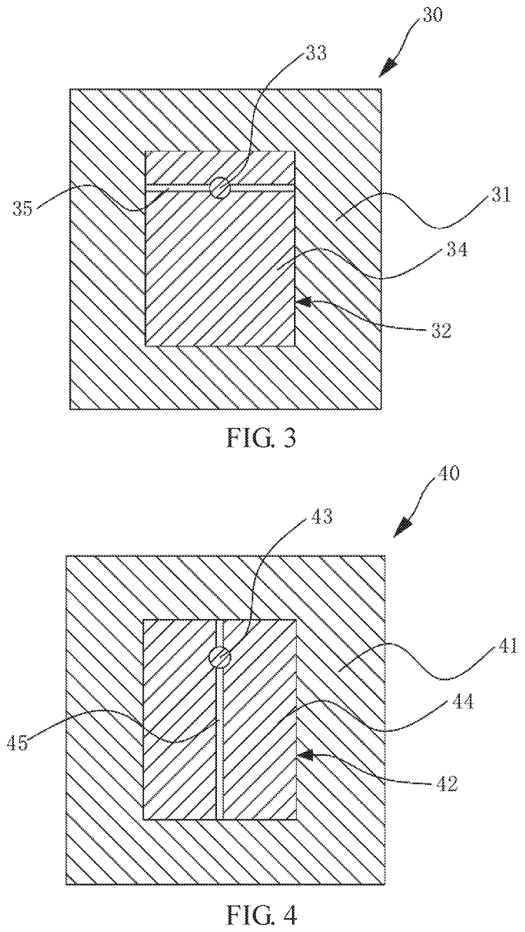

As shown in FIG. 3, the second mask plate 30 includes a main body 31 and an opening region 32, and the opening region 32 is provided with a block portion 33, two connectors 34, and an evaporation zone 35.

The two connectors 34 are respectively located at two sides of the block portion 33, and the block portion 33 is fixedly connected to the main body 31.

The evaporation zone 35 of the second mask plate 30 is divided into two second sub-evaporation zones by the block portion 33 and the connector 34. The two second sub-evaporation zones are the same size as and overlap with the first connector 14 and the second connector 15 of the first mask plate 10, respectively.

As shown in FIG. 4, the third mask plate 40 includes a main body 41 and an opening region 42. The opening region 42 is provided with a block portion 43, two connectors 44, and an evaporation zone 45.

The two connectors 44 are respectively located at two sides of the block portion 43, and the block portion 43 is fixedly connected to the main body 41.

The evaporation zone 45 of the third mask plate 40 is separated into two third sub-evaporation zones by the block portion 43 and the connector 45. The two third sub-evaporation zones are the same size as and overlap with the third connector and the fourth connector of the first mask plate 10, respectively.

The first mask plate 10, the second mask plate 30, and the third mask plate 40 are used as a complete set of a mask plate assembly and used for performing three evaporations, respectively. During evaporation, the material is evaporated in the region corresponding to the evaporation zone 18 by the first mask plate 10, and then the second mask plate 30 is used for evaporating the material in the area corresponding to the evaporation zone 35, i.e., the areas which are shielded by the first connector 14 and the second connector 15 of the first mask plate. At last, the material is evaporated in the area corresponding to the evaporation zone 45 by the third mask plate 40, i.e., the areas which are shielded by the third connector 16 and the fourth connector 17 of the first mask plate 10. The evaporation of the OLED device in this embodiment is accomplished with three mask plates. The effect that the opening region, except a portion thereof which is shielded by the block portion, is sufficiently coated with the evaporation material is finally achieved.

### Third Embodiment

As shown in FIG. 1 and FIGS. 5-8, the mask plate assembly provided in this embodiment includes five matching mask plates as a complete set, namely, a first mask plate 10, a second mask plate 50, a third mask plate 60, a fourth mask plate 70 and a fifth mask plate 80.

During the evaporation coating, the first mask plate 10 is used to perform the first evaporation. Since the predetermined area of the opening region corresponding to the four connectors of the first mask plate 10 for connecting the block portion is blocked during the first evaporation, therefore, the evaporation cannot be completed merely by the first evaporation. The evaporation procedure of the OLED device is divided into four steps to realize the evaporation coating of the predetermined area of the opening region, whereby the area which is not coated by evaporation by the first evaporation can be finally coated by evaporation. The second mask plate 50, the third mask plate 60, the fourth mask plate 70, and the fifth mask plate 80 provided in this embodiment are designed for evaporating the material to the area shielded by the first connector 14, the second connector 15, the third connector 16 and the fourth connector 17 of the first mask plate 10.

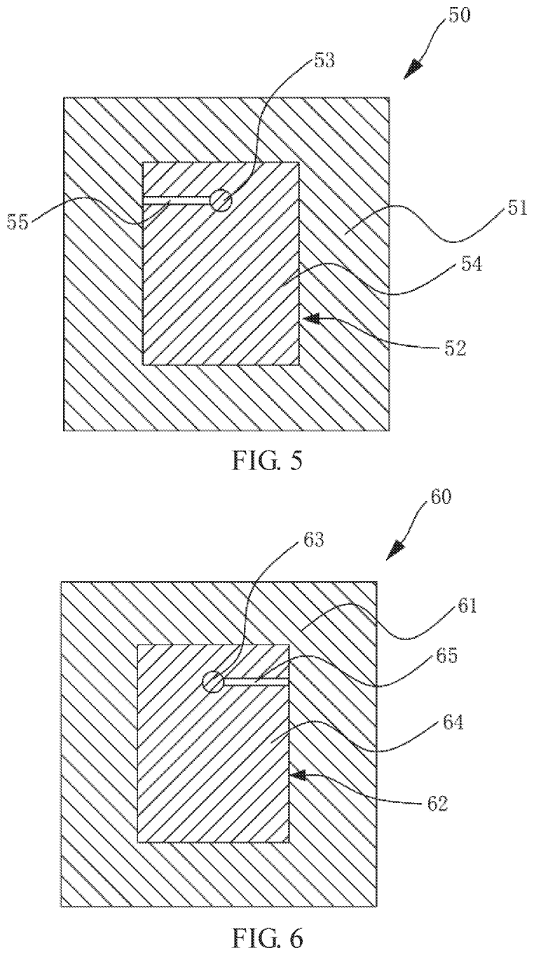

As shown in FIG. 5, the second mask plate 50 includes a main body 51 and an opening region 52. The opening region is provided with a block portion 53, a connector 54 and an evaporation zone 55.

The connector 54 is fixedly connected to the main body 51 and the block portion 53. The mask plate 50 is a one-piece structure, and the evaporation zone 55 is formed by an etching process. The evaporation zone 55 has a strip structure. The evaporation zone 55 is the same size as and overlaps with the first connector 14 of the first mask plate 10.

As shown in FIG. 6, the third mask plate 60 includes a main body 61 and an opening region 62. The opening region is provided with a block portion 63, a connector 64 and an evaporation zone 65.

The connector 64 is fixedly connected to the main body 61 and the block portion 63. The evaporation zone 65 has a strip structure. The evaporation zone 65 is the same size as and overlaps with the second connector 15 of the first mask plate 10.

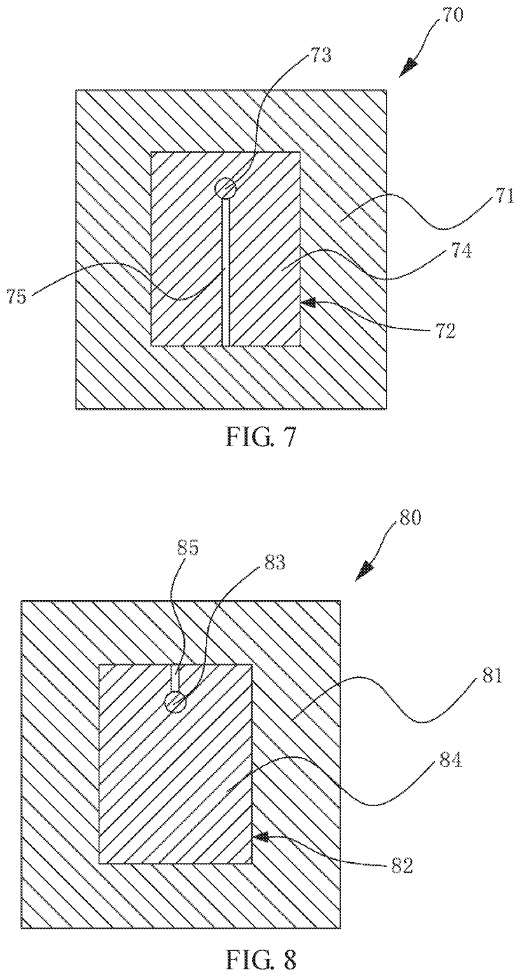

As shown in FIG. 7, the fourth mask plate 70 includes a main body 71 and an opening region 72, and the opening region is provided with a block portion 73, a connector 74, and an evaporation zone 75.

The connector 74 is fixedly connected to the main body 71 and the block portion 73. The evaporation zone 75 has a strip structure, and the evaporation zone 75 has the same size as and overlaps with the third connector 16 of the first mask plate 10.

As shown in FIG. 8, the fifth mask plate 80 includes a main body 81 and an opening region 82, and the opening region is provided with a block portion 83, a connector 84, and an evaporation zone 85.

The connector 84 is fixedly connected to the main body 81 and the block portion 83. The evaporation zone 85 has a strip structure, and the evaporation zone 85 has the same size as and overlaps with the fourth connector 17 of the first mask plate 10.

The mask plate assembly provided in this embodiment is used with five evaporation steps during evaporation procedure of the OLED device. The first mask plate 10 is used for the first evaporation. The evaporation coating to the area corresponding to the block portion and the four connectors of the first mask plate 10 is completed by the next four evaporation steps with the other four mask plates respectively, and the second mask plate 50, the third mask plate 60, the fourth mask plate 70. The fifth mask plate 80 provided in this embodiment are used in no particular order.

An advantage of the present invention is in that the mask plate assembly provided by the present invention includes matching mask plates. The mask plates complete the evaporation coating by several steps, thereby to accomplish that a specific area of the display is void of evaporation material. Thus, a camera can be built into the display to facilitate the realization of a full screen display.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A mask plate assembly for evaporation, comprising at least two mask plates forming a complete set, the mask plate comprising:
a main body;
an opening region, in which is provided with a block portion, at least one connector, and an evaporation zone;
wherein the connector is connected to the main body and the block portion;
wherein a size of the connector of one of the at least two mask plates is the same as a size of the evaporation zone of the other mask plate and the positions of the connector and the evaporation zone thereof are overlapped, the evaporation zone of at least two mask plates are matched each other, the at least two mask plates each are one-piece structure, and the block portion, the connector, and the evaporation zone in each of the at least two mask plates are formed by the same etching process.

2. The mask plate assembly according to claim 1, wherein the mask plate assembly includes a first mask plate and a second mask plate.

3. The mask plate assembly according to claim 2, wherein the first mask plate forms a first connector, a second connector, a third connector and a fourth connector in the opening region thereof.

4. The mask plate assembly according to claim 3, wherein each of the first connector, the second connector, the third connector, and the fourth connector has one end connected to the main body and another end connected to the block portion.

5. The mask plate assembly according to claim 4, wherein the first connector, the second connector, the third connector, the fourth connector, and the block portion together define a cross structure, and the block portion is located at an intersection of the cross structure.

6. The mask plate assembly according to claim 5, wherein the evaporation zone of the second mask plate is divided into four first sub-evaporation zones, and the contours of the four first sub-evaporation zones are substantially the same as the shapes of the first connector, the second connector, the third connector, and the fourth connector respectively.

7. A mask plate assembly for evaporation, comprising at least two mask plates forming a complete set, the mask plate comprising:
a main body;
an opening region, in which is provided with a block portion, at least one connector, and an evaporation zone;
wherein the connector is connected to the main body and the block portion;
wherein a size of the connector of one of the at least two mask plates is the same as a size of the evaporation zone of the other mask plate and the positions of the connector and the evaporation zone thereof are overlapped, the evaporation zone in each of the at least two mask plates are matched each other.

8. The mask plate assembly according to claim 7, wherein the mask plate assembly includes a first mask plate and a second mask plate.

9. The mask plate assembly according to claim 8, wherein the first mask plate forms a first connector, a second connector, a third connector and a fourth connector in the opening region thereof.

10. The mask plate assembly according to claim 9, wherein each of the first connector, the second connector, the third connector, and the fourth connector has one end connected to the main body and another end connected to the block portion.

11. The mask plate assembly according to claim 10, wherein the first connector, the second connector, the third connector, and the fourth connector has a shape in strip.

12. The mask plate assembly according to claim 11, wherein the first connector and the second connector are connected as a straight line, and also the third connector and the fourth connector are connected as a straight line.

13. The mask plate assembly according to claim 12, wherein the first connector, the second connector, the third connector, the fourth connector, and the block portion together define a cross structure, and the block portion is located at an intersection of the cross structure.

14. The mask plate assembly according to claim 13, wherein the evaporation zone of the second mask plate is divided into four first sub-evaporation zones, and the contours of the four first sub-evaporation zones are substantially the same as the shapes of the first connector, the second connector, the third connector, and the fourth connector respectively.

15. The mask plate assembly according to claim 13, further comprising a third mask plate.

16. The mask plate assembly according to claim 15, wherein the evaporation zone of the second mask plate is divided into two second sub-evaporation zones, and the contours of the two second sub-evaporation zones are substantially the same as the shapes of the first connector and the second connector of the first mask plate respectively.

17. The mask plate assembly according to claim 16, wherein the evaporation zone of the third mask plate is divided into two third sub-evaporation zones, and the contours of the two third sub-evaporation zones are substantially the same as the shapes of the third connector and the fourth connector of the first mask plate respectively.

18. The mask plate assembly according to claim 15, further comprising a fourth mask plate and a fifth mask plate.

19. The mask plate assembly according to claim 18, wherein the contours of each evaporation zone of the second mask plate, the third mask plate, the fourth mask plate and the fifth mask plate are substantially the same as the shapes of the first connector, the second connector, the third connector and the fourth connector of the first mask plate respectively.

20. The mask plate assembly according to claim 13, wherein the shape of the block portion of the first mask plate is a circular or a rectangular.
